(19) United States
(12) Patent Application Publication
(10) Pub. No.: US 2018/0205013 A1
(43) Pub. Date: Jul. 19, 2018

(54) RESISTIVE RANDOM ACCESS MEMORY (RRAM) AND FORMING METHOD THEREOF

(71) Applicant: UNITED MICROELECTRONICS CORP., Hsin-Chu City (TW)

(72) Inventors: Liang Yi, Singapore (SG); Chia-Ching Hsu, Yunlin County (TW); Shen-De Wang, Hsinchu County (TW); Ko-Chi Chen, Taoyuan City (TW)

(21) Appl. No.: 15/441,261

(22) Filed: Feb. 24, 2017

(30) Foreign Application Priority Data
Jan. 16, 2017 (CN) 201710032325.1

(51) Int. Cl. H01L 45/00; H01L 27/24

(52) U.S. Cl. CPC H01L 45/124; H01L 45/1683; H01L 27/2436; H01L 45/1253; H01L 45/08; H01L 45/146

(57) ABSTRACT

A method of forming a Resistive Random Access Memory (RRAM) includes the following steps. A first dielectric layer is formed on a first electrode layer. A second dielectric layer having a first trench is formed on the first dielectric layer. Spacers are formed beside sidewalls of the first trench. Apart of the first dielectric layer exposed by the spacers is removed, thereby forming a second trench in the first dielectric layer. A resistance switching material fills in the second trench. The second dielectric layer and the spacers are removed. A second electrode layer is formed on the resistance switching material and the first dielectric layer. The present invention also provides a RRAM formed by said method.

### BACKGROUND OF THE INVENTION

### 1. Field of the Invention

The present invention relates generally to a resistive random access memory (RRAM) and forming method thereof, and more specifically to a resistive random access memory (RRAM) and forming method thereof applying spacers to define a size of a resistance switching material.

### 2. Description of the Prior Art

Since nonvolatile memory devices can store data even while power is turned off, many electrical products must have such memory devices to reserve data. Resistive random access memory (RRAM) devices—one kind of nonvolatile memory devices —are developed in the industry. The resistive random access memory (RRAM) devices have the advantages of low programming voltage, short erasing time, long memory time, nondestructive reading, multi memory states, simple structures and small areas, so the resistive random access memory (RRAM) devices will become widely used in personal computers and electronic equipment.

In integrated circuit (IC) devices, resistive random access memory (RRAM) can be integrated for the next generation. A resistive random access memory (RRAM) is a memory structure that includes an array of resistive random access memory cells. Each resistive random access memory cell stores one bit data through a resistance value rather than charges. In particular, each of the resistive random access memory cells includes a resistance switching material layer, which can represent a logic “0” or a logic “1” by adjusting resistance values.

One way to optimize resistive random access memory cell arrays is to make them smaller. However, due to process limitations, the size of resistive random access memory cell arrays has reached the physical limit in modern processes. Thus, it becomes a major challenge in the industry to improve the resistance random access memory cell arrays.

### SUMMARY OF THE INVENTION

The present invention provides a resistive random access memory (RRAM) and forming method thereof, which applies spacers to define the size and the location of a resistance switching material, thereby the size of the resistance switching material can be less than a critical dimension. Hence, this shrinks the formed resistive random access memory (RRAM).

The present invention provides a method of forming a Resistive Random Access Memory (RRAM) including the following steps. A first dielectric layer is formed on a first electrode layer. A second dielectric layer is formed on the first dielectric layer, wherein the second dielectric layer includes a first trench. Spacers are formed on sidewalls of the first trench. A part of the first dielectric layer exposed by the spacers is removed, thereby a second trench being formed in the first dielectric layer. A resistance switching material fills in the second trench. The second dielectric layer and the spacers are removed. A second electrode layer is formed on the resistance switching material and the first dielectric layer.

The present invention provides Resistive Random Access Memory (RRAM) including a first electrode layer, a dielectric layer, a resistance switching material and a second electrode layer. The dielectric layer is disposed on the first electrode layer, wherein the dielectric layer has a second trench. The resistance switching material is disposed in second trench. The second electrode layer is disposed on the resistance switching material.

According to the above, the present invention provides a resistive random access memory (RRAM) and forming method thereof, which forms spacers on sidewalls of a first trench to reduce a width of a second trench being formed below the spacers by self-aligning the spacers. Thereby, this reduces the size of a resistance switching material in the second trench, shrinks the formed resistive random access memory (RRAM), and optimizes the performance of the resistive random access memory (RRAM).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a method of forming a Resistive Random Access Memory (RRAM) according to an embodiment of the present invention.

FIG. 2 schematically depicts a cross-sectional view of a method of forming a Resistive Random Access Memory (RRAM) according to an embodiment of the present invention.

FIG. 3 schematically depicts a cross-sectional view of a method of forming a Resistive Random Access Memory (RRAM) according to an embodiment of the present invention.

FIG. 4 schematically depicts a cross-sectional view of a method of forming a Resistive Random Access Memory (RRAM) according to an embodiment of the present invention.

FIG. 5 schematically depicts a cross-sectional view of a method of forming a Resistive Random Access Memory (RRAM) according to an embodiment of the present invention.

FIG. 6 schematically depicts a cross-sectional view of a method of forming a Resistive Random Access Memory (RRAM) according to an embodiment of the present invention.

FIG. 7 schematically depicts a cross-sectional view of a method of forming a Resistive Random Access Memory (RRAM) according to an embodiment of the present invention.

FIG. 8 schematically depicts a cross-sectional view of a method of forming a Resistive Random Access Memory (RRAM) according to an embodiment of the present invention.

FIG. 9 schematically depicts a cross-sectional view of a method of forming a Resistive Random Access Memory (RRAM) according to an embodiment of the present invention.

FIG. 10 schematically depicts a cross-sectional view of a structure of a Resistive Random Access Memory (RRAM) according to an embodiment of the present invention.

### DETAILED DESCRIPTION

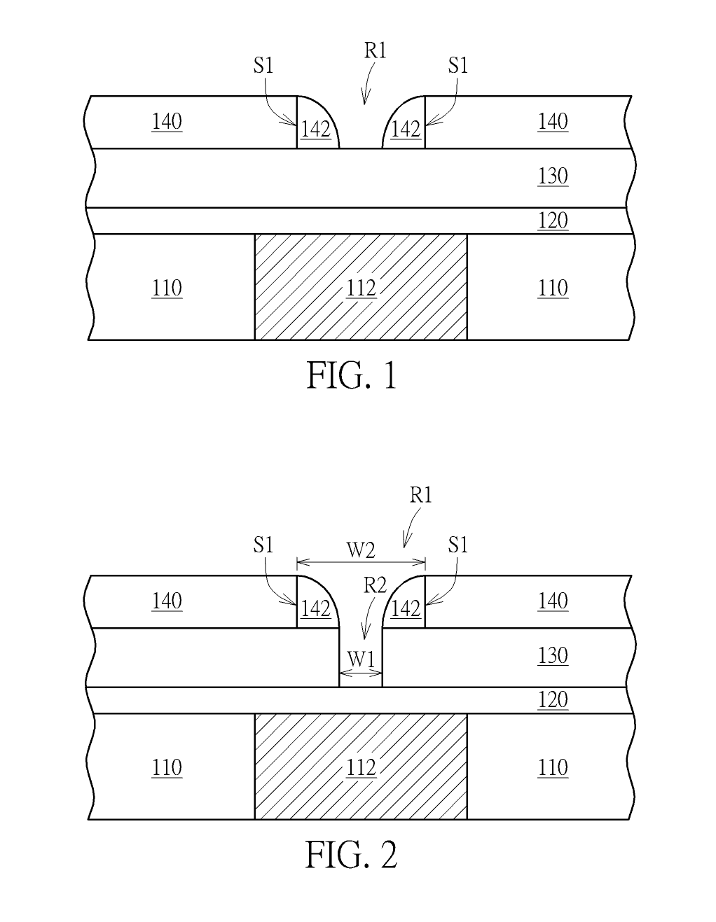

FIGS. 1-9 schematically depict cross-sectional views of a method of forming a Resistive Random Access Memory (RRAM) according to an embodiment of the present invention. As shown in FIG. 1, a first electrode layer 120 is formed on a dielectric layer 110. The dielectric layer 110 may include an oxide layer, but it is not limited thereto. In this embodiment, the dielectric layer 110 may be an inter-metal dielectric layer (IMD), but in another embodiment, the dielectric layer 110 may be an interdielectric layer (ILD), depending up practical requirements. At least a first metal 112 is located in the dielectric layer 110, wherein the first metal 112 may be a contact plug, but it is not limited thereto. The first metal 112 is disposed right below the first electrode layer 120, and the first metal 112 directly contacts the first electrode layer 120. The first metal 112 may have conductive materials such as copper (Cu) or aluminum (Al). The first electrode layer 120 may have conductive materials such as aluminum (Al), copper (Cu), platinum (Pt), tantalum (Ta) or tantalum nitride (TaN). A first dielectric layer 130 is formed on the first electrode layer 120. A second dielectric layer 140 is formed on the first dielectric layer 130. The second dielectric layer 140 includes a first trench R1. The method of forming the second dielectric layer 140 may include the following steps. A second dielectric layer (not shown) may blanketly cover the first dielectric layer 130, and the second dielectric layer (not shown) is patterned to form the second dielectric layer 140, which includes the first trench R1. Preferably, the first dielectric layer 130 and the second dielectric layer 140 have different etching rates, therefore the first dielectric layer 130 can be an etching stop layer while etching the second dielectric layer 140 to form the first trench R1. Thereby, the first trench R1 is formed and the first dielectric layer 130 is exposed without etching the first dielectric layer 130. In one case, the first dielectric layer 130 and the second dielectric layer 140 preferably have different materials for having etching selectivity to the etching processes of etching the second dielectric layer 140 or other required properties. In this case, the first dielectric layer 130 may be a nitride layer, and the second dielectric layer 140 may be an oxide layer, but it is not limited thereto. In another case, the first dielectric layer 130 may be an oxide layer, and the second dielectric layer 140 may be a nitride layer.

Then, spacers 142 are formed on sidewalls S1 of the first trench R1. The method of forming the spacers 142 may include the following. A spacer material (not shown) may blanketly cover the second dielectric layer 140 and the first dielectric layer 130, and the spacer material (not shown) overflowing out from the first trench R1 is removed to form the spacers 142. The spacers 142 and the second dielectric layer 140 preferably have common materials for being removed at the same time in later processes. Furthermore, the spacers 142 and the first dielectric layer 130 preferably have different materials for the first dielectric layer 130 being preserved while the spacer material (not shown) is etched to form the spacers 142. Accordingly, while the spacers 142 and the first dielectric layer 130 have different materials and the spacers 142 and the second dielectric layer 140 have common materials, the first dielectric layer 130 and the second dielectric layer 140 inherently have different materials. In this case, since the first dielectric layer 130 is a nitride layer while the second dielectric layer 140 is an oxide layer, the spacers 142 are oxide spacers, but it is not limited thereto.

As shown in FIG. 2, a part of the first dielectric layer 130 exposed by the spacers 142 is removed, thereby a second trench R2 being formed in the first dielectric layer 130. That is, the second trench R2 is formed in the first dielectric layer 130 by self-aligning the spacers 142. In the present invention, the spacers 142 are formed on the sidewalls S1 of the first trench R1, therefore a width W1 of the second trench R2 is reduced. This means the width W1 of the second trench R2 being less than a width W2 of the first trench R1 can be less than a critical dimension while the width W2 of the first trench R1 approaches the critical dimension by applying the method of forming the spacers 142 on the sidewalls S1 of the first trench R1 of the present invention.

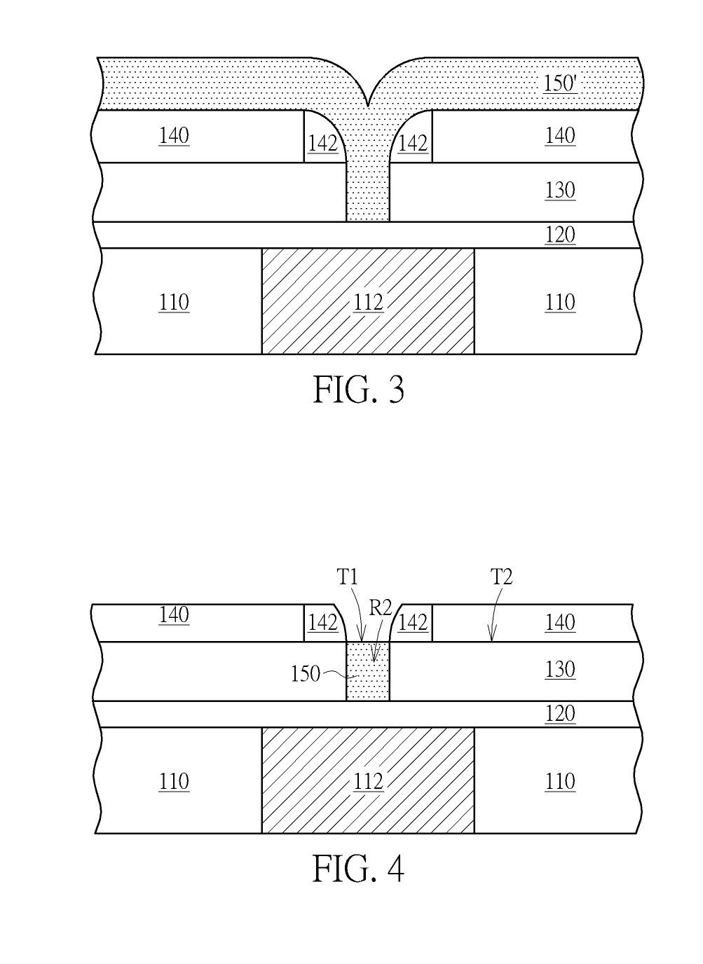

Please refer to FIGS. 3-4, in which a resistance switching material 150 fills the second trench R2. The method of filling the resistance switching material 150 in the second trench R2 may include, but is not limited to, the following steps. As shown in FIG. 3, conformally depositing a resistance switching material 150′ is performed in the second trench R2 and on the second dielectric layer 140, wherein the resistance switching material 150′ must fill up the second trench R2. The resistance switching material 150′ may be formed by a physical vapor deposition (PVD) process such as sputtering or an atomic layer deposition (ALD) process etc. As shown in FIG. 4, the resistance switching material 150′ overflowing out from the second trench R2 is removed, thereby the resistance switching material 150 being formed. The resistance switching material 150′ may be removed by etching or chemical mechanical polishing (CMP) processes etc. The spacers 142 and the second dielectric layer 140 may be partially etched while the resistance switching material 150′ is removed. In this case, the resistance switching material 150 fills up the second trench R2, and a top surface T1 of the resistance switching material 150 trims a top surface T2 of the first dielectric layer 130, hence a later formed second electrode layer can directly contact the resistance switching material 150 smoothly. The resistance switching material 150 may include transition metal oxide. The transition metal oxide may be hafnium oxide, tantalum oxide, titanium oxide, nickel oxide, etc.

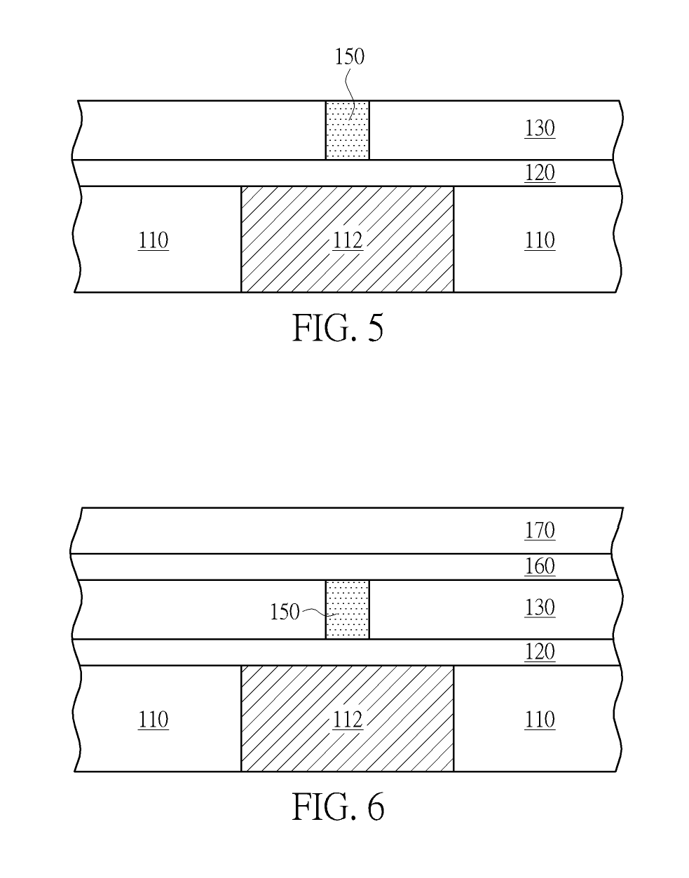

The second dielectric layer 140 and the spacers 142 are removed, as shown in FIG. 5. Preferably, the second dielectric layer 140 and the spacers 142 may be removed by an oxide strip process, but it is not limited thereto. Since the second dielectric layer 140 and the spacers 142 are composed of oxide, the second dielectric layer 140 and the spacers 142 can both be removed by the an oxide strip process. Hence, this simplifies processes.

As shown in FIG. 6, a second electrode layer 160 is formed on the resistance switching material 150 and the first dielectric layer 130. The second electrode layer 160 may include conductive materials such as aluminum (Al), platinum (Pt), tantalum (Ta), tantalum nitride (TaN), copper (Cu), etc. A cap layer 170 may be formed on the second electrode layer 160, wherein the cap layer 170 may be an oxide cap layer, but it is not limited thereto.

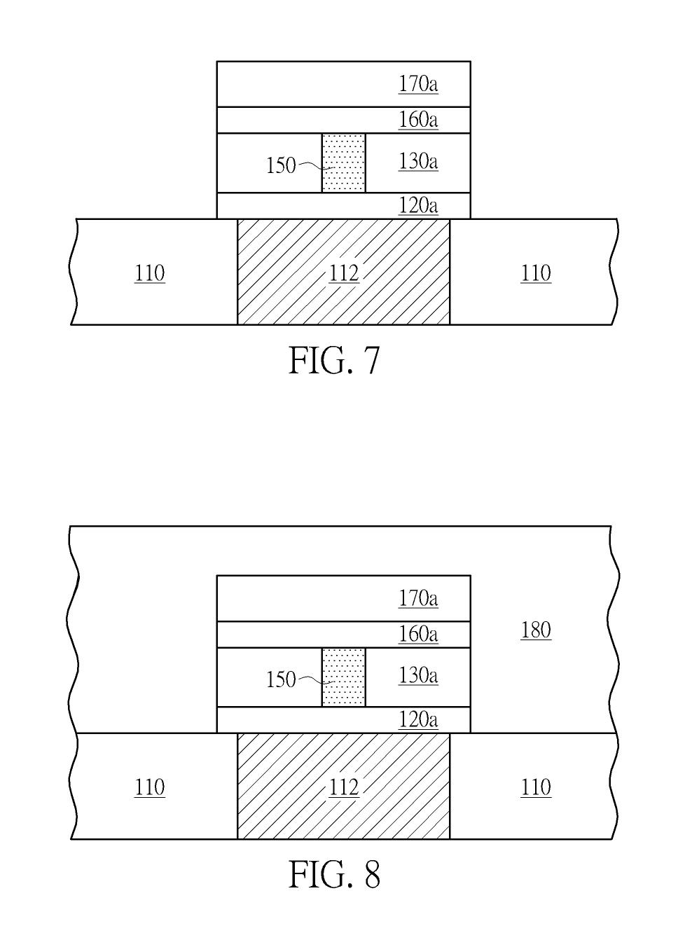

Thereafter, the cap layer 170, the second electrode layer 160, the first dielectric layer 130 and the first electrode layer 120 may be patterned by methods such as etching and photolithography processes to form a first electrode layer 120a, a first dielectric layer 130a, an second electrode layer 160a and a cap layer 170a, as shown in FIG. 7. As shown in FIG. 8, a dielectric layer 180 is deposited to blanketly cover the first electrode layer 120a, the first dielectric layer 130a, the second electrode layer 160a, the cap layer 170a and the dielectric layer 110. The dielectric layer 180 may be an oxide layer, which may be an inter-metal dielectric layer (IMD), but it is not limited thereto. For instance, as the dielectric layer 110 is a first-level inter-metal dielectric layer, the dielectric layer 180 may be a second-level inter-metal dielectric layer (IMD).

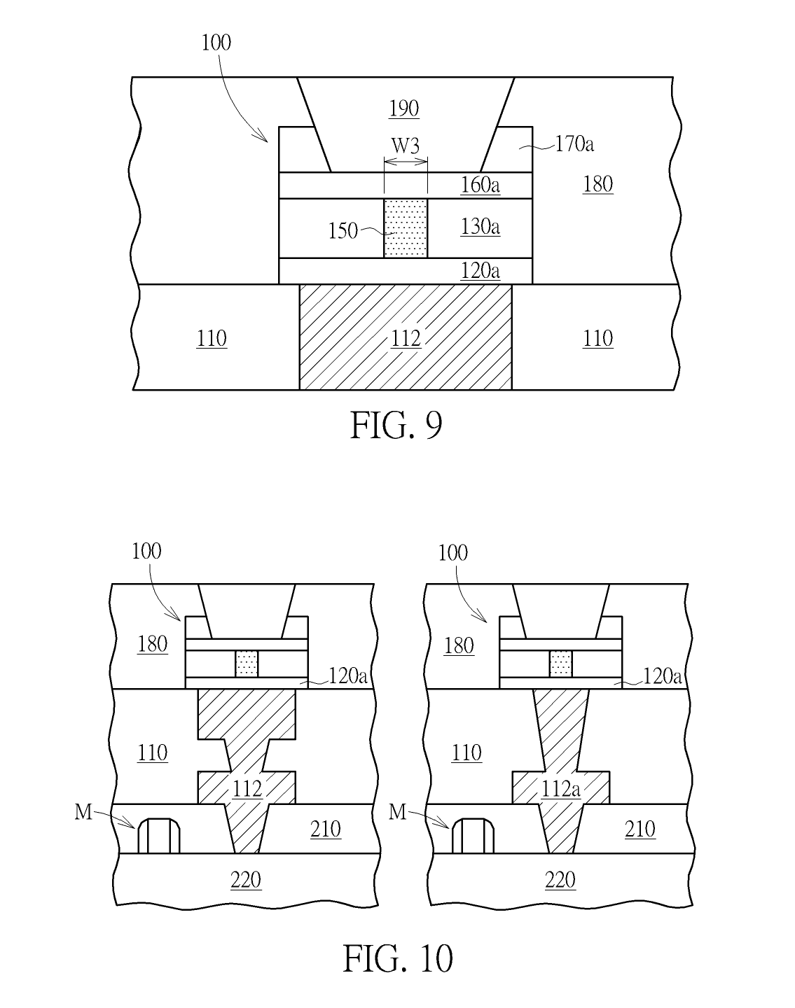

As shown in FIG. 9, a second metal 190 is formed in the dielectric layer 180, and the second metal 190 is right above the second electrode layer 160a and directly contacts the second electrode layer 160a. The second metal 190 may be a contact plug, but it is not limited thereto. The contact plug may have metal materials such as copper (Cu), aluminum (Al), etc.

Above all, a Resistive Random Access Memory (RRAM) 100 is formed in the dielectric layer 180 in the present invention. The first dielectric layer 130a is disposed on the first electrode layer 120a. The first dielectric layer 130a may be a dielectric layer. The resistance switching material 150 is disposed in the first dielectric layer 130a. The second electrode layer 160a is disposed on the resistance switching material 150. In the present invention, the spacers 142 are formed (as shown in FIGS. 3-4), and the resistance switching material 150 is formed by self-aligning the spacers 142, thereby a width W3 of the resistance switching material 150 (which equals to the width W1 of the second trench R2) being less than a critical dimension, and shrinking the Resistive Random Access Memory (RRAM) 100. As the sizes of the resistance switching material 150 and the Resistive Random Access Memory (RRAM) 100 are shrunk, the resistance difference of the resistance switching material 150 between a logic “0” and a logic “1” becomes larger, hence the performance of the Resistive Random Access Memory (RRAM) 100 becomes better.

FIG. 10 schematically depicts a cross-sectional view of a structure of a Resistive Random Access Memory (RRAM) according to an embodiment of the present invention. The left diagram and the right diagram of FIG. 10 depict the Resistive Random Access Memory (RRAM) 100 of the present invention being formed on different interconnect structures or contact plugs. The Resistive Random Access Memory (RRAM) 100 of the present invention is formed in the dielectric layer 180 (a second-level inter-metal dielectric layer) and on the dielectric layer 110 (a first-level inter-metal dielectric layer). The dielectric layer 110 is formed on an interdielectric layer (ILD) 210, wherein the interdielectric layer (ILD) 210 may be an oxide layer. A MOS transistor M may be further included in the interdielectric layer (ILD) 210 beside the Resistive Random Access Memory (RRAM) 100, and the MOS transistor M and the interdielectric layer (ILD) 210 may be both formed on a substrate 220. The left diagram and the right diagram of FIG. 10 have the first electrode layer 120a connecting different shapes of first metals 112 /112a respectively. The first metal 112 directly contacting the first electrode layer 120a have a larger contacting area than that of the first metal 112a directly contacting the first electrode layer 120a, depending upon practical requirements.

To summarize, the present invention provides a resistive random access memory (RRAM) and forming method thereof, which forms spacers on sidewalls of a first trench to reduce a width of a second trench being formed below the spacers by self-aligning the spacers. Thereby, this reduces the size of a resistance switching material in the second trench, shrinks the formed resistive random access memory (RRAM), and optimizes the performance of the resistive random access memory (RRAM). As a width of the first trench approaches a critical dimension, a width of the resistance switching material can be less than the critical dimension, thus the purpose of shrinking the Resistive Random Access Memory (RRAM) can be achieved.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a Resistive Random Access Memory (RRAM), comprising:
forming a first dielectric layer on a first electrode layer;
forming a second dielectric layer on the first dielectric layer, wherein the second dielectric layer comprises a first trench;
forming spacers on sidewalls of the first trench;
removing a part of the first dielectric layer exposed by the spacers, thereby a second trench being formed in the first dielectric layer;
filling a resistance switching material in the second trench;
removing the second dielectric layer and the spacers; and
forming a second electrode layer on the resistance switching material and the first dielectric layer.

2. The method of forming a Resistive Random Access Memory (RRAM) according to claim 1, wherein the first dielectric layer and the second dielectric layer have different etching rates.

3. The method of forming a Resistive Random Access Memory (RRAM) according to claim 2, wherein the first dielectric layer and the second dielectric layer have different materials.

4. The method of forming a Resistive Random Access Memory (RRAM) according to claim 3, wherein the first dielectric layer comprises a nitride layer, and the second dielectric layer comprises an oxide layer.

5. The method of forming a Resistive Random Access Memory (RRAM) according to claim 1, wherein the spacers comprise oxide spacers.

6. The method of forming a Resistive Random Access Memory (RRAM) according to claim 1, wherein the spacers and the first dielectric layer have different materials.

7. The method of forming a Resistive Random Access Memory (RRAM) according to claim 6, wherein the spacers and the second dielectric layer have common materials.

8. The method of forming a Resistive Random Access Memory (RRAM) according to claim 7, wherein the spacers and the second dielectric layer are removed by an oxide strip process.

9. The method of forming a Resistive Random Access Memory (RRAM) according to claim 1, wherein the second trench is formed by etching the first dielectric layer through self-aligning the spacers.

10. The method of forming a Resistive Random Access Memory (RRAM) according to claim 1, wherein a width of the second trench is less than a critical dimension.

11. The method of forming a Resistive Random Access Memory (RRAM) according to claim 1, wherein the resistance switching material comprises transition metal oxide.

12. The method of forming a Resistive Random Access Memory (RRAM) according to claim 11, wherein the method of filling the resistance switching material in the second trench comprises:
conformally depositing a resistance switching material in the second trench and on the spacers and the second dielectric layer; and
removing the resistance switching material overflowing out from the second trench.

13. A Resistive Random Access Memory (RRAM), comprising:
a dielectric layer disposed on a first electrode layer, wherein the dielectric layer has a trench;
a resistance switching material disposed in trench; and
a second electrode layer disposed on the resistance switching material.

14. The Resistive Random Access Memory (RRAM) according to claim 13, wherein the dielectric layer comprises a nitride layer.

15. The Resistive Random Access Memory (RRAM) according to claim 13, further comprising:
a first metal disposed below the first electrode layer and directly contacting the first electrode layer, and a second metal disposed on the second electrode layer and directly contacting the second electrode layer.

16. The Resistive Random Access Memory (RRAM) according to claim 15, wherein the first metal and the second metal comprise contact plugs.

17. The Resistive Random Access Memory (RRAM) according to claim 16, wherein the contact plugs comprise in an interdielectric layer (ILD) or/and in an inter-metal dielectric layer (IMD).

18. The Resistive Random Access Memory (RRAM) according to claim 13, wherein the resistance switching material comprises transition metal oxide.

19. The Resistive Random Access Memory (RRAM) according to claim 18, wherein the transition metal oxide comprises hafnium oxide, tantalum oxide, titanium oxide or nickel oxide, and the first electrode layer and the second electrode layer comprise platinum (Pt), tantalum (Ta), tantalum nitride (TaN) or copper (Cu).

20. The Resistive Random Access Memory (RRAM) according to claim 13, wherein a width of the resistance switching material is less than a critical dimension.
